(19) United States
(12) Patent Application Publication
(10) Pub. No.: US 2025/0203849 A1
(43) Pub. Date: Jun. 19, 2025

(54) SEMICONDUCTOR DEVICE

(71) Applicant: Samsung Electronics Co., Ltd., Suwon-si (KR)

(72) Inventors: Deokhwan Choi, Suwon-si (KR); TAEYUN KIM, Suwon-si (KR); KYO-SEON CHOI, Suwon-si (KR)

(21) Appl. No.: 18/744,657

(22) Filed: Jun. 16, 2024

(30) Foreign Application Priority Data
Dec. 18, 2023 (KR) 10-2023-0185027

(51) Int. Cl. H10B 12/00

(52) U.S. Cl. CPC H10B 12/482; H10B 12/315; H10B 12/488

(57) ABSTRACT

The disclosure relates to a semiconductor device including a substrate, a lower insulation layer above the substrate, a bit line above the lower insulation layer and extending parallel to the substrate in a first direction, a first insulating pattern above the bit line and extending in a second direction intersecting the first direction, a channel pattern electrically connected to the bit line and covering the side of the first insulating pattern, a word line extending in the second direction and spaced apart from the channel pattern, a gate insulating pattern between the channel pattern and the word line, a second insulating pattern above the word line, the gate insulating pattern, and the first insulating pattern, and a landing pad electrically connected to the channel pattern, wherein a part of the word line is between a plurality of bit lines arranged spaced apart in the second direction.

### CROSS-REFERENCE TO RELATED APPLICATION

This application claims priority and the benefit thereof under 35 U.S.C. § 119 to Korean Patent Application No. 10-2023-0185027, filed in the Korean Intellectual Property Office on Dec. 18, 2023, the entire contents of which are incorporated herein by reference.

### BACKGROUND OF THE DISCLOSURE

### 1. Field of the Disclosure

The present disclosure relates to a semiconductor device.

### 2. Description of the Related Art

There is a need to increase an integration of semiconductor memory devices to meet an excellent performance and a low price demanded by consumers. In the case of the semiconductor memory devices, particularly the increased integration is required because the integration is an important factor in determining the price of the product.

In the case of two-dimensional or plane semiconductor memory devices, the integration is mainly determined by the area occupied by a unit memory cell, so it is greatly influenced by the level of a fine pattern formation technology. However, because ultra-expensive equipment is required to refine the pattern, the integration of the 2D semiconductor memory devices is increasing but still limited. Accordingly, semiconductor memory devices including a vertical channel transistor of which a channel extends in the vertical direction are being proposed.

### SUMMARY OF THE DISCLOSURE

Embodiments are intended to provide semiconductor devices with improved electric characteristics.

A semiconductor device according to an embodiment includes a substrate, a lower insulation layer positioned above the substrate, a bit line positioned above the lower insulation layer and extending parallel to the substrate in a first direction, a first insulating pattern positioned above the bit line and extending in a second direction intersecting the first direction, a channel pattern electrically connected to the bit line and covering the side of the first insulating pattern, a word line extending in the second direction and spaced apart from the channel pattern, a gate insulating pattern positioned between the channel pattern and the word line, a second insulating pattern positioned above the word line, the gate insulating pattern, and the first insulating pattern, and a landing pad electrically connected to the channel pattern, wherein a part of the word line is positioned between a plurality of bit lines arranged spaced apart in the second direction.

A semiconductor device according to an embodiment includes a substrate, a lower insulation layer positioned on the substrate, a bit line positioned above the lower insulation layer and extending parallel to the substrate in a first direction, a first insulating pattern positioned above the bit line and extending in a second direction intersecting the first direction, a channel pattern electrically connected to the bit line and covering a side of the first insulating pattern, a word line extending in the second direction and spaced apart from the channel pattern, a gate insulating pattern positioned between the channel pattern and the word line, a second insulating pattern positioned on the word line, the gate insulating pattern, and the first insulating pattern, and a landing pad electrically connected to the channel pattern, wherein the word line includes parts protruded in a third direction vertical to the substrate towards the upper surface of the lower insulation layer, and each of the protruded parts of the word line is positioned between bit lines adjacent in the second direction.

A semiconductor device according to an embodiment includes a substrate, a lower insulation layer positioned on the substrate, a bit line positioned above the lower insulation layer and extending parallel to the substrate in a first direction, a first insulating pattern positioned above the bit line and extending in a second direction intersecting the first direction, a channel pattern electrically connected to the bit line and covering the side of the first insulating pattern, a word line extending in the second direction and spaced apart from the channel pattern, a gate insulating pattern positioned between the channel pattern and the word line, a second insulating pattern positioned on the word line, the gate insulating pattern, and the first insulating pattern, and a landing pad electrically connected to the channel pattern, wherein the bit line has an upper surface at a higher vertical level than the upper surface of the lower insulation layer, and a portion of the bit line positioned at a higher vertical level than the upper surface of the lower insulation layer overlaps with the word line in the second direction and in a third direction vertical to the substrate.

According to embodiments, a contact resistance may be reduced by increasing the contact area of the bit line and the channel pattern.

Additionally, according to embodiments, the word line may serve as a shield wire between the adjacent bit lines.

### BRIEF DESCRIPTION OF THE DRAWINGS

FIG. 1 is a layout diagram to explain a semiconductor device according to example embodiments.

FIG. 2 is a view showing cross-sections of a semiconductor device according to an example embodiment of FIG. 1 taken along lines A-A′ and B-B′.

FIG. 3 is an enlarged view of a part P1 of FIG. 2.

FIG. 4 and FIG. 5 are cross-sectional views of a semiconductor device according to example embodiments.

FIG. 6 is a layout diagram to explain a semiconductor device according to an example embodiment.

FIG. 7 is a view showing cross-sections of a semiconductor device according to an example embodiment of FIG. 6 taken along lines A-A′ and B-B′.

FIG. 8, FIG. 11, FIG. 14, FIG. 17, FIG. 20, FIG. 23, FIG. 26, FIG. 29, and FIG. 32 are layout views showing a manufacturing method of a semiconductor device according to an example embodiment.

FIG. 9, FIG. 10, FIG. 12, FIG. 13, FIG. 15, FIG. 16, FIG. 18, FIG. 19,

FIG. 21, FIG. 22, FIG. 24, FIG. 25, FIG. 27, FIG. 28, FIG. 30, FIG. 31, FIG. 33, and FIG. 34 are cross-sectional views showing a manufacturing method of a semiconductor device according to an example embodiment.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Parts unrelated to the description of the exemplary embodiments are not shown to make the description clear, and like reference numerals designate like element throughout the specification.

The size and thickness of the configurations are optionally shown in the drawings for convenience of description, and the present disclosure is not limited to the drawings. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, or as “contacting” or “in contact with” another element (or using any form of the word “contact”), there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

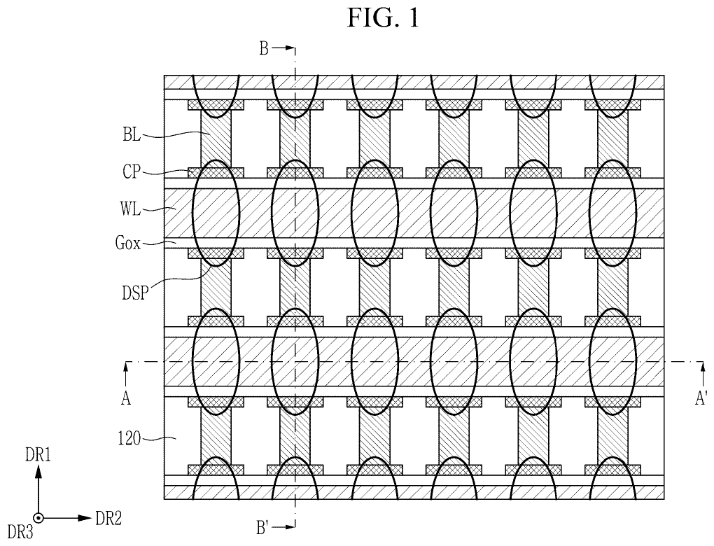

Hereinafter, a semiconductor device according to an embodiment is described with reference to FIG. 1 to FIG. 3.

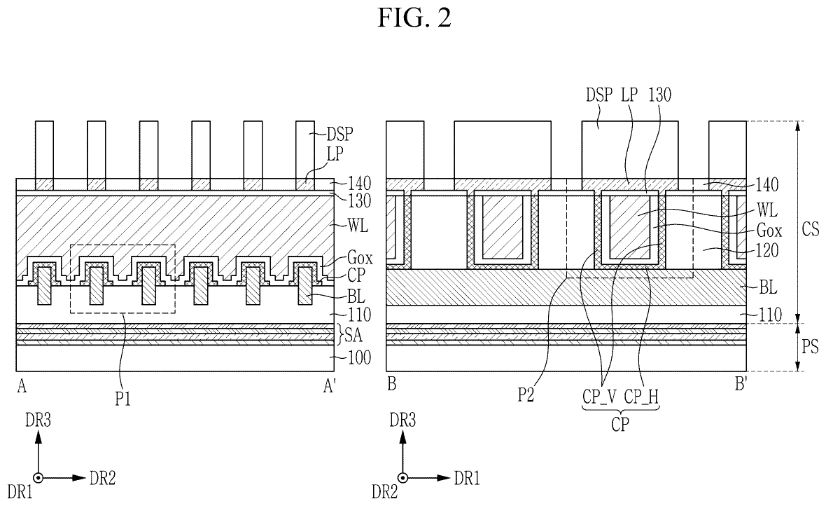

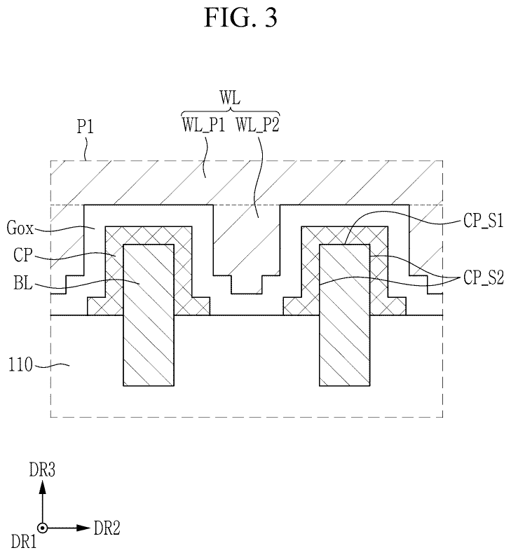

FIG. 1 is a layout diagram to explain a semiconductor device according to example embodiments. FIG. 2 is a view showing cross-sections of a semiconductor device according to an example embodiment of FIG. 1 taken along lines A-A′ and B-B′. FIG. 3 is an enlarged view of a part P1 of FIG. 2.

Referring to FIG. 1 to FIG. 3, a semiconductor device according to an embodiment may include a peripheral circuit structure PS and a cell array structure CS disposed on the peripheral circuit structure PS.

The peripheral circuit structure PS may include a substrate 100, a core and peripheral circuits SA integrated on the upper surface of the substrate 100. The substrate 100 may have a structure in which a base substrate and an epitaxial layer are stacked, but embodiments are not limited thereto. For example, the substrate 100 may be a silicon substrate, gallium arsenic substrate, a silicon germanium substrate, or a semiconductor on insulator (SOI) substrate. Hereinafter, the substrate 100 will be described as a silicon substrate.

The core and peripheral circuits SA may include NMOS and PMOS transistors integrated on the substrate 100. The core and peripheral circuits SA may be electrically connected to the bit lines BL through the peripheral circuit wires and the peripheral circuit contact plugs. For example, sense amplifiers may be electrically connected to the bit lines BL, and each sense amplifier may amplify and output a difference in voltage levels detected in the pair of bit lines BL.

The cell array structure CS may include memory cells including a vertical channel transistor (VCT). The vertical channel transistor may refer to a structure in which the channel length extends in a vertical direction with respect to the upper surface of the substrate 100.

In an embodiment, the cell array structure CS may include a lower insulation layer 110, bit lines BL, first insulating patterns 120, channel patterns CP, word lines WL, gate insulating patterns Gox, a second insulating pattern 130, landing pads LP, an interlayer insulating layer 140, and data storing patterns DSP.

The lower insulation layer 110 may be positioned above the substrate 100. The lower insulation layer 110 may cover the core and peripheral circuits SA, the peripheral circuit wires, and the peripheral circuit contact plugs on the substrate 100. The lower insulation layer 110 may include multi-layered insulating layers. For example, the lower insulation layer 110 may be formed of or include a silicon oxide layer, a silicon nitride layer, a silicon oxynitride layer, and/or a low dielectric layer.

The bit line BL may be positioned above the lower insulation layer 110. A lower surface of the bit line BL may contact an upper surface of the lower insulation layer 110. The upper surface of the bit line BL may have a higher upper surface than the upper surface of the lower insulation layer 110. For example, the upper surface of the bit line BL may be at a higher vertical level than the upper surface of the lower insulation layer 110. The bit line BL may be extended in parallel to the substrate 100 in the first direction DR1. The bit lines BL may be arranged to be spaced apart in the second direction DR2, which intersects the first direction DR1. For example, the second direction DR2 may be a direction perpendicular to the first direction DR1.

According to an embodiment, the bit line BL may be surrounded by the lower insulation layer 110. The bottom surface of the bit line BL may be positioned at a lower vertical level than the upper surface of the lower insulation layer 110. A portion of both sides of the bit line BL adjacent to the bottom surface and the bottom surface of the bit line BL may be surrounded by the lower insulation layer 110. For example, the lower insulation layer 110 may contact side and bottom surfaces of the bit line BL. In other words, the part of both sides extending from the bottom surface and the bottom surface of the bit line BL may be surrounded by the lower insulation layer 110. The upper surface of the bit line BL and the upper part of both sides extending from the upper surface may be surrounded by the channel pattern CP, which will be described later.

The bit line BL may be formed of or include a doped polysilicon, a metal, conductive metal nitride, a conductive metal silicide, a conductive metal oxide, or combinations thereof. For example, the bit lines BL may be formed of Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOx, RuOx, or a combination thereof, but embodiments are not limited thereto. The bit line BL may include a single layer or multiple layers of the materials described above.

In some embodiments, the bit line BL may include a two-dimensional semiconductor material, for example, graphene, carbon nanotube, or a combination thereof.

The first insulating patterns 120 may be positioned above the bit line BL and be extended in the second direction DR2. Lower surfaces of the first insulating patterns 120 may contact upper surfaces of the bit lines BL. The first insulating patterns 120 may be arranged to intersect the bit lines BL. The first insulating patterns 120 may be arranged spaced apart in the first direction DR1.

The first insulating pattern 120 may be formed of or include at least one of, for example, silicon oxide, silicon oxynitride, silicon nitride, or a low dielectric constant (low-k) material that has a dielectric constant smaller than silicon oxide, but embodiments are not limited thereto.

The low dielectric constant material, for example, may include at least one among flowable oxide (FOX), torene silazene (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, or a combination thereof, but embodiments are not limited thereto.

The channel pattern CP may be positioned above the bit line BL. The channel pattern CP may be electrically connected to the bit line BL. The channel pattern CP may include a first source/drain region and a second source/drain region. For example, the lower part of the channel pattern CP is connected to the bit line BL and may function as a first source/drain region, the upper part of the channel pattern CP is connected to the landing pad LP and may function as a second source/drain region, and a portion of the channel pattern CP between the first source/drain region and the second source/drain region may function as a channel region.

The channel patterns CP may be in contact with the bit lines BL and the first insulating patterns 120. The channel pattern CP may be in contact with the upper surface of the bit line BL. The channel pattern CP may be in contact with the sides facing each other of the adjacent first insulating patterns 120 in the first direction DR1. The channel pattern CP may be positioned between the first insulating patterns 120 adjacent in the first direction DR1. The channel patterns CP and the first insulating patterns 120 may be alternately and repeatedly arranged along the first direction DR1. The plurality of channel patterns CP may be arranged and spaced apart in the first direction DR1. Additionally, the plurality of channel patterns CP may be arranged and spaced apart in the second direction DR2.

The channel patterns CP may be approximately “U” shaped on a cross-section cut along the first direction DR1 and the third direction DR3. Each of the channel patterns CP may include a horizontal part CP_H covering the bit line BL and vertical parts CP_V covering the opposing sides of the adjacent first insulating patterns 120. The vertical parts of the channel pattern CP may each extend from the horizontal part CP_H in a third direction DR3 vertical to the substrate 100. The vertical parts CP_V may extend in the third direction DR3 along the opposing sides of the adjacent first insulating patterns 120. The vertical parts CP_V of the channel pattern CP may be connected to a landing pad LP, which will be described later.

The upper surface of the vertical part CP_V of the channel pattern CP may be positioned at substantially the same vertical level as the upper surface of the first insulating pattern 120, but embodiments are not limited thereto. In some embodiments, the upper surface of the vertical part CP_V of the channel pattern CP may be positioned at a lower vertical level than the upper surface of the first insulating pattern 120. In this case, the landing pad LP may include a portion positioned between the first insulating pattern 120 and a gate insulating pattern Gox, which will be described later.

The channel pattern CP may have a conformal shape. The thickness of the horizontal part CP_H and the thickness of the vertical parts CP_V of the channel pattern CP may be constant. The thickness of the horizontal part CP_H may mean a thickness in the third direction DR3, and the thickness of the vertical part CP_V may mean a thickness in the first direction DR1.

On the cross-section of the channel pattern CP along the second direction DR2 and the third direction DR3, the channel pattern CP may surround three sides of the bit line BL. The channel pattern CP may surround the upper surface of the bit line BL and a portion of both sides of the bit line BL extending from the upper surface of the bit line BL. According to the above, the upper surface of the lower insulation layer 110 may be positioned at a level between the upper surface and the bottom surface of the bit line BL. The part of both sides of the bit line BL may include a part positioned at a higher vertical level than the upper surface of the lower insulation layer 110. For example, the portion of the bit line BL positioned at a vertical level higher than the upper surface of the lower insulation layer 110 may be surrounded by the channel pattern CP.

The channel pattern CP may be in contact with the upper surface and both side surfaces of the bit line BL. Referring to FIG. 3, the channel pattern CP may include a first surface CP_S1 in contact with the upper surface of the bit line BL, and second surfaces CP_S2 in contact with both sides of the bit line BL. The second surfaces CP_S2 of the channel pattern CP each may be in contact with a respective side surface of the bit line BL, which is positioned at a higher vertical level than the upper surface of the lower insulation layer 110.

The contact area of the channel pattern CP and the bit line BL may correspond to the area of the first surface CP_S1 and the second surfaces CP_S2. For example, as the contact area of the channel pattern CP and the bit line BL increases, a contact resistance may decrease. According to a comparative example in which the channel pattern CP is in contact with only the upper surface of the bit line BL, the contact area of the channel pattern CP and the bit line BL may correspond to the area of the first surface CP_S1. According to an embodiment, the contact area of the channel pattern CP and bit line BL increases by the area of the second surfaces CP_S2, so the contact resistance may be reduced compared to the comparative example.

The channel patterns CP may cover a portion of the upper surface of the lower insulation layer 110 positioned on both sides of the bit line BL. Lower surfaces of the channel patterns CP may contact portion of the upper surface of the lower insulation layer 110 on either side of the bit line BL. As shown in FIG. 3, the channel pattern CP may include a portion protruded in a direction away from bit line BL along the upper surface of the lower insulation layer 110 from a portion extending in the third direction DR3 along the side of bit line BL, but embodiments are not limited thereto. In some embodiments, the portion of the channel pattern CP that extends in the third direction DR3 along the side of bit line BL may not include the protruded portion. For example, the width of the portion of the channel pattern CP covering the side of the bit line BL along the first direction DR1 may be constant.

For example, the channel pattern CP may include an oxide semiconductor material. The oxide semiconductor material may be a combination of at least two of In, Ga, Zn, Al, Sn, and Hf, but embodiments are not limited thereto. The oxide semiconductor material may further include materials such as Si, Mg, Ta, La, Nd, Ce, Sc, Cr, Co, Nb, Mo, Ba, Gd, Ti, W, Pd, Ru, Ni, or Mn to the above composition.

For example, the channel pattern CP may include indium gallium zinc oxide (IGZO), indium tin zinc oxide (ITZO), indium zinc oxide IZO( ) zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide (IGO) or a combination thereof. However, embodiments are not limited to this, and the oxide semiconductor material included in the channel pattern CP may be changed in various ways.

According to an embodiment, the channel pattern CP may include indium gallium zinc oxide (IGZO).

The word lines WL may be positioned above the channel patterns CP. The word lines WL may be positioned above the horizontal part CP_H of the channel patterns CP. The word lines WL may be positioned between the vertical parts CP_V of the channel pattern CP. According to an embodiment, one word line WL may be positioned between the vertical parts CP_V of the channel pattern CP.

The word lines WL may be extended lengthwise in the second direction DR2. The word lines WL may be arranged to intersect the bit lines BL. The word lines WL may be arranged spaced apart in the first direction DR1. The word lines WL may be spaced apart from the channel patterns CP. The word lines WL may be separated from the channel patterns CP by a gate insulating pattern Gox, which will be described later.

On a cross-section cut along the first direction DR1 and the third direction DR3, the word line WL may include an upper surface and a bottom surface facing in the third direction DR3 and both sides facing in the first direction DR1. According to an embodiment, the upper surfaces of the word lines WL may be positioned at substantially the same vertical level as the upper surface of the channel patterns CP. The bottom surface of the word line WL may face the bit line BL with the gate insulating pattern Gox and the channel pattern CP in between. Both sides of the word line WL may face the vertical parts CP_V of the channel pattern CP with the gate insulating pattern Gox in between.

On a cross-section cut along the second direction DR2 and the third direction DR3, the word line WL may include a first portion WL_P1 covering the upper surfaces of the bit lines BL arranged in the second direction DR2 and extending in the second direction DR2 and second portions WL_P2 extending (or protruding) from the bottom surface of the first portion WL_P1 toward the upper surface of the lower insulation layer 110 in the third direction DR3. The second portions WL_P2 may be respectively positioned between the bit lines BL adjacent to each other in the second direction DR2. The second portions of the word line WL, WL_P2 may serve as a shield wire between the bit lines BL adjacent to the second direction DR2.

According to an embodiment, the word line WL may overlap with the bit line BL in the second direction DR2 and the third direction DR3. The first portion WL_P1 of the word line WL may overlap with the bit line BL in the third direction DR3. The second portions WL_P2 of the word line WL may overlap with the bit line BL in the second direction DR2, respectively.

The word line WL may include, for example, doped polysilicon, metal, conductive metal nitride, conductive metal silicide, conductive metal oxide, or combinations thereof. The word line WL, for example, may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but embodiments are not limited thereto.

The word line WL may include a single layer or multiple layers of the materials described above. In some embodiments, the word line WL may include a two-dimensional semiconductor material, for example, the two-dimensional semiconductor material may include graphene, carbon nanotube, or a combination thereof.

The gate insulating pattern Gox may be positioned between the word line WL and the channel pattern CP. The gate insulating pattern Gox may be positioned on the channel pattern CP between the first insulating patterns 120 adjacent in the first direction DR1. The gate insulating pattern Gox may be formed conformally on the channel pattern CP.

On a cross-section cut along the first direction DR1 and the third direction DR3, the gate insulating pattern Gox may conformally cover the horizontal part CP_H and the vertical parts CP_V of the channel pattern CP. For example, the gate insulating pattern Gox may contact the horizontal part CP_H and the vertical parts CP_V of the channel pattern CP. According to an embodiment, the word line WL may fill the space left after the gate insulating pattern Gox is formed on the channel patterns CP arranged in the second direction DR2.

On a cross-section cut along the first direction DR1 and the third direction DR3, the upper surface of the gate insulating pattern Gox positioned between the side of the word line WL and the vertical part CP_V of the channel pattern CP may be positioned at substantially the same vertical level as the upper surface of the channel pattern CP, but embodiments are not limited thereto. In some embodiments, the upper surface of the channel pattern CP may be positioned at a lower vertical level than the upper surface of the gate insulating pattern Gox.

On a cross-section cut along the second direction DR2 and the third direction DR3, the gate insulating pattern Gox may conformally cover the channel patterns CP arranged in the second direction DR2 and the lower insulation layer 110 positioned between the channel patterns CP adjacent in the second direction DR2. For example, the gate insulating pattern Gox may contact the channel patterns CP arranged in the second direction DR2 and the lower insulation layer 110 positioned between the channel patterns CP adjacent in the second direction DR2.

The gate insulating pattern Gox may include silicon oxide, silicon oxynitride, a high dielectric constant material with a dielectric constant higher than silicon oxide, or a combination thereof. The high dielectric constant material may include a metal oxide or a metal oxynitride. The high dielectric constant material may be, for example, HfO2, HfSiO, HfSiON, HfTaO, HfTiO, HfZrO, ZrO2, Al2O3, or a combination thereof. However, embodiments are not limited to this, and the material included in the gate insulating pattern Gox may be changed in various ways.

The second insulating pattern 130 may be positioned above the word line WL, the gate insulating pattern Gox, and the first insulating pattern 120. The second insulating pattern 130 may cover the upper surface of the word lines WL, the upper surface of the gate insulating patterns Gox, and the upper surface of the first insulating patterns 120. For example, the second insulating pattern 130 may contact the upper surface of the word lines WL, the upper surface of the gate insulating patterns Gox, and the upper surface of the first insulating patterns 120. The upper surface of the vertical parts CP_V of the channel pattern CP may be exposed by the second insulating pattern 130.

The second insulating pattern 130 may include at least one of, for example, silicon oxide, silicon oxynitride, silicon nitride, or a low dielectric constant (low-k) material that has a dielectric constant smaller than silicon oxide, but embodiments are not limited thereto.

The landing pad LP may be electrically connected to the channel pattern CP. The landing pad LP may be in contact with at least part of the channel pattern CP. The landing pad LP may be in contact with the upper surface of the vertical parts CP_V of the channel pattern CP exposed by the second insulating pattern 130.

According to an embodiment, the vertical parts CP_V of the channel pattern CP may be connected to the same landing pad LP. On a cross-section cut along first direction DR1 and third direction DR3, the landing pads LP may overlap with the horizontal part CP_H and the vertical parts CP_V of the channel pattern CP in the third direction DR3, respectively. As shown in FIG. 2, the landing pad LP may have a width greater than the width of the channel pattern CP along the first direction DR1, but embodiments are not limited thereto. In some embodiments, the landing pad LP may have a width that is substantially the same as the width of the channel pattern CP along the first direction DR1.

The landing pad LP may be in contact the vertical part CP_V of the channel pattern CP that penetrates the opening defined by the second insulating pattern 130 in the third direction DR3. In FIG. 2, the upper surface of the vertical part CP_V of the channel pattern CP may be positioned at substantially the same vertical level as the upper surface of the first insulating pattern 120 and the upper surface of the gate insulating pattern Gox. In this case, the contact surface of the landing pad LP and the channel pattern CP may be positioned at substantially the same vertical level as the upper surface of the first insulating pattern 120 and the upper surface of the gate insulating pattern Gox, but embodiments are not limited thereto. In some embodiments, the upper surface of the vertical part CP_V of the channel pattern CP may be positioned at a lower vertical level than the upper surface of the first insulating pattern 120 and the upper surface of the gate insulating pattern Gox, and in this case, the contact surface between the landing pad LP and the channel pattern CP may be positioned between the first insulating pattern 120 and the gate insulating pattern Gox. The landing pad LP may be further positioned between the first insulating pattern 120 and the gate insulating pattern Gox.

The landing pads LP may be arranged to be spaced apart from each other in the first direction DR1 and the second direction DR2. The landing pads LP may be arranged in a matrix form, but this is only an example and embodiments are not limited to this. The landing pads LP may be arranged in various layouts, such as a honeycomb shape. The landing pads LP may be spaced apart by an interlayer insulating layer 140, which will be described later.

The landing pad LP may have a shape such as circular, oval, rectangle, square, rhombus, or hexagon on a plane, but the plane shape of the landing pad LP is not limited to these.

The landing pad LP may include a doped polysilicon, a metal, a conductive metal nitride, a conductive metal oxide, or combinations thereof. For example, the landing pad LP may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or combinations thereof, but embodiments are not limited thereto.

The interlayer insulating layer 140 may be positioned above the second insulating pattern 130. The interlayer insulating layer 140 may be in contact with the upper surface of the second insulating pattern 130. The interlayer insulating layer 140 may fill the space between the landing pads LP arranged spaced apart in the first direction DR1 on the second insulating pattern 130. The sides of the landing pads LP may be surrounded by an interlayer insulating layer 140. For example, the interlayer insulating layer 140 may contact side surfaces of the landing pads LP.

The interlayer insulating layer 140 may include at least one of, for example, silicon oxide, silicon oxynitride, silicon nitride, or a low dielectric constant (low-k) material that has a dielectric constant smaller than silicon oxide, but embodiments are not limited thereto.

In some embodiments, the interlayer insulating layer 140 may include the same insulating material as the second insulating pattern 130. In this case, the interface between the interlayer insulating layer 140 and the second insulating pattern 130 may not be identified.

The data storing patterns DSP may be disposed on the landing pads LP. For example, lower surfaces of the data storing patterns DSP may contact upper surfaces of the landing pads LP. The data storing pattern DSP may be electrically connected to each channel pattern CP through the landing pad LP. The data storing patterns DSP, as shown in FIG. 1, may be arranged in matrix form along the first direction DR1 and the second direction DR2.

In an embodiment, the data storing pattern DSP may be a capacitor and may include lower and upper electrodes and a capacitor dielectric layer interposed between them. If the data storing pattern DSP is a capacitor, the lower electrode may be in contact with the landing pad LP, and the lower electrode may have various shapes such as circular, oval, rectangle, square, rhombus, and hexagon in a plane.

In contrast, the data storing pattern DSP may be a variable resistor pattern that may be switched between two resistance states by an electrical pulse applied to a memory element. For example, data storing pattern DSP may include a phase-change material of which a crystal state changes depending on the amount of current, a perovskite compound, a transition metal oxide, and a magnetic material, a ferromagnetic material or an antiferromagnetic material.

According to an embodiment of the semiconductor device, the contact resistance may be reduced by increasing the contact area of the bit line BL and the channel pattern CP. Additionally, according to an embodiment of the semiconductor device, the word line WL includes the portions positioned between the adjacent bit lines BL, so that the word line WL may serve as a shield wire between the adjacent bit lines BL. Accordingly, the electric characteristics of the semiconductor device may be improved.

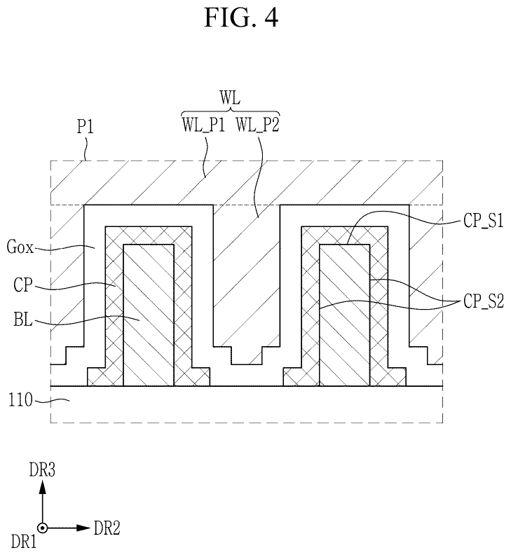

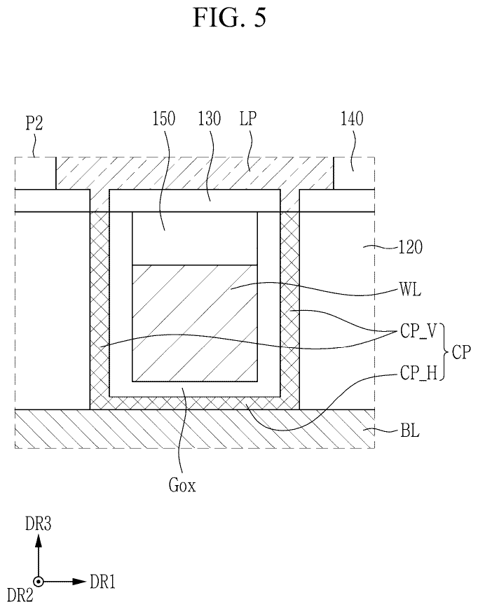

Hereinafter, another example embodiment of the semiconductor device is described with reference to FIG. 4 and FIG. 5. In the following embodiments, the same components as the above-described embodiments are referred to by the same reference numerals, duplicate descriptions are omitted or simplified, and differences are mainly explained.

FIG. 4 and FIG. 5 are cross-sectional views of a semiconductor device according to other example embodiments. FIG. 4 is an enlarged view of a region corresponding to a region P1 of FIG. 2. FIG. 5 is an enlarged view of a region corresponding to a region P2 of FIG. 2.

Referring to FIG. 4, unlike the embodiment of FIG. 1 to FIG. 3, the upper surface of the lower insulation layer 110 may be positioned at almost the same vertical level as the bottom surface of the bit line BL. For example, the lower insulation layer 110 may be in contact with the bottom surface of the bit line BL and not in contact with the side of the bit line BL. Accordingly, the upper surface and both sides of the bit line BL may be surrounded by the channel pattern CP. The channel pattern CP may completely surround the upper surface and both sides of the bit line BL. For example, the channel pattern CP may contact the upper surface and the entirety of both sides of the bit line BL.

The channel pattern CP may include a first surface CP_S1 in contact with the upper surface of the bit line BL and a second surface CP_S2 in contact with both sides of the bit line BL. The second surfaces CP_S2 may each be in contact with the side of the bit line BL positioned at a higher vertical level than the upper surface of the lower insulation layer 110. According to the embodiment of FIG. 4, unlike the embodiment of FIG. 1 to FIG. 3, the entire side of the bit line BL may be positioned at a higher vertical level than the upper surface of the lower insulation layer 110. Accordingly, the area of the second surfaces CP_S2 of the embodiment FIG. 4 may be wider than the area of the second surfaces CP_S2 of the embodiment of FIG. 3.

The word line WL may include a first portion WL_P1 covering the upper surfaces of the bit lines BL arranged in the second direction DR2 and extending in the second direction DR2, and second portions WL_P2 extending from the bottom surface of the first portion WL_P1 to the upper surface of the lower insulation layer 110 in the third direction DR3. The second portions WL_P2 may each be positioned between the adjacent bit lines BL in the second direction DR2.

The upper surface of the lower insulation layer 110 of the embodiment of FIG. 4 may be positioned at almost the same vertical level as the lower surface of the bit line BL. The upper surface of the lower insulation layer 110 of the embodiment of FIG. 4 may be positioned at a lower vertical level than the upper surface of the lower insulation layer 110 in the embodiment of FIG. 1 to FIG. 3. Accordingly, the width of the second portions WL_P2 of the embodiment of FIG. 4 along the third direction DR3 may be larger than the width of the second portions WL_P2 of the embodiment of FIG. 1 to FIG. 3 along the third direction DR3. In other words, in the embodiment of FIG. 4, the area where the bit line BL and the word line WL overlap in the second direction DR2 may be wider than that of the embodiment of FIG. 1 to FIG. 3.

According to the embodiment of FIG. 4, the contact area of the bit line BL and the channel pattern CP may be further increased than that of the embodiment of FIG. 1 to FIG. 3. Accordingly, the contact resistance between the bit line BL and the channel pattern CP may be further reduced.

Referring to FIG. 5, unlike the embodiment of FIG. 1 to FIG. 3, the word line WL may be separated from the second insulating pattern 130. The word line WL and the second insulating pattern 130 may be separated in the third direction DR3. The upper surface of the word line WL may be positioned at a lower vertical level than the upper surface of the vertical parts CP_V of the channel pattern CP. The upper surface of the word line WL may be positioned at a lower vertical level than the upper surface of the gate insulating pattern Gox, which extends in the third direction DR3 along the vertical part CP_V of the channel pattern CP.

An additional insulating pattern 150 may be positioned between the word line WL and the second insulating pattern 130. The additional insulating pattern 150 may be positioned between the parts of the gate insulating pattern Gox positioned at a higher vertical level than the upper surface of the word line WL. The additional insulating pattern 150 may fill the space between the upper surface of the word line WL, the bottom surface of the second insulating pattern 130, and the opposing sides of the gate insulating pattern Gox. An upper surfaces of the additional insulating pattern 150 may be positioned at the same vertical level as upper surfaces of the gate insulating pattern Gox. The additional insulating pattern 150 may be extended in the second direction DR2 along the word line WL.

The additional insulating pattern 150 may include at least one of, for example, silicon oxide, silicon oxynitride, silicon nitride, or a low dielectric constant (low-k) material that has a dielectric constant smaller than silicon oxide, but embodiments are not limited thereto.

In the embodiment of FIG. 1 to FIG. 3, in which the second insulating pattern 130 is positioned on the first insulating pattern 120, the gate insulating pattern Gox, and the word line WL, in the embodiment of FIG. 5, the second insulating pattern 130 may be positioned on the first insulating pattern 120, the gate insulating pattern Gox, and the additional insulating pattern 150. According to the embodiment of FIG. 5, the second insulating pattern 130 may cover the upper surface of the first insulating pattern 120, the upper surface of the gate insulating pattern Gox, and the upper surface of the additional insulating pattern 150. For example, the second insulating pattern 130 may contact the upper surface of the first insulating pattern 120, the upper surface of the gate insulating pattern Gox, and the upper surface of the additional insulating pattern 150.

In the embodiment of FIG. 1 to FIG. 3, in which the second insulating pattern 130 is in contact with the upper surface of the word line WL, in the embodiment of FIG. 5, the second insulating pattern 130 may be in contact with the upper surface of the additional insulating pattern 150.

In the embodiment of FIG. 1 to FIG. 3, while the contact surface of the landing pad LP and the channel pattern CP may be positioned at substantially the same vertical level as the upper surface of the word line WL, in the embodiment of FIG. 5, the upper surface of the word line WL may be positioned at a lower vertical level than the contact surface of the landing pad LP and the channel pattern CP. According to the embodiment of FIG. 5, the word line WL may be spaced further apart from the landing pad LP than the embodiment of FIG. 1 to FIG. 3. Accordingly, a possibility of a short occurring between the word line WL and the landing pad LP may be reduced.

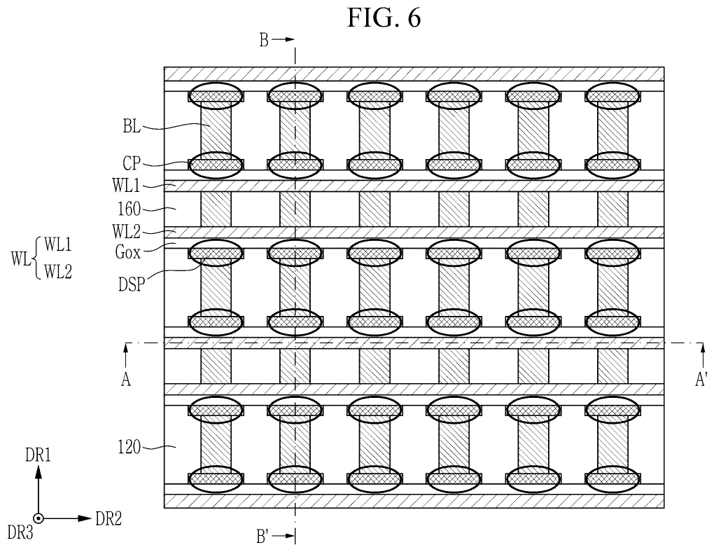

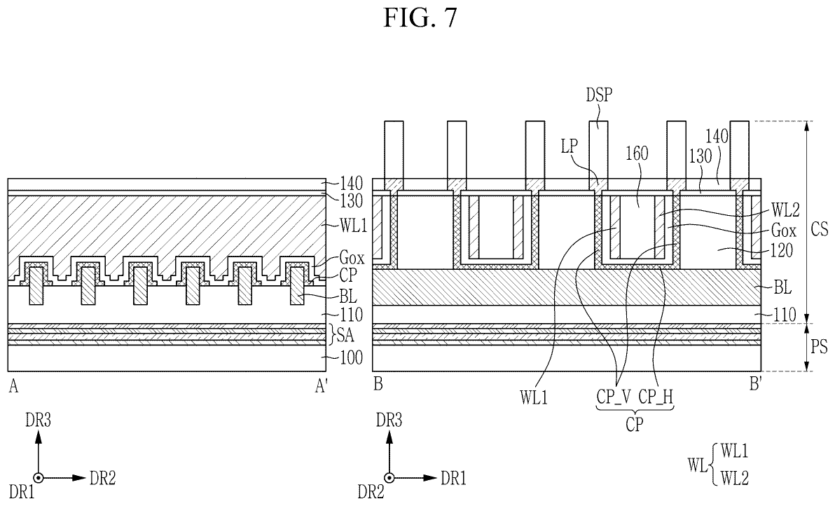

Hereinafter, another implementation of the semiconductor device is explained with reference to FIG. 6 and FIG. 7. In the following embodiments, the same components as the above-described embodiments are referred to by the same reference numerals, duplicate descriptions are omitted or simplified, and differences are mainly explained.

FIG. 6 is a layout diagram to explain a semiconductor device according to an example embodiment. FIG. 7 is a view showing cross-sections of a semiconductor device according to an example embodiment of FIG. 6 taken along lines A-A′ and B-B′.

Referring to FIG. 6 and FIG. 7, like the embodiment of FIG. 1 to FIG. 3, the plurality of first insulating patterns 120 may be arranged to be spaced apart along the first direction DR1, and the channel pattern CP may be positioned between the first insulating patterns 120 adjacent in the first direction DR1. The first insulating patterns 120 and the channel patterns CP may be alternately and repeatedly arranged along the first direction DR1.

On a cross-section cut along the first direction DR1 and the third direction DR3, the channel pattern CP may include a horizontal part CP_H covering the bit line BL and vertical parts CP_V extending from the horizontal part CP_H in the third direction DR3 and facing in the first direction DR1. The horizontal part CP_H of the channel pattern CP may cover the upper surface of the bit line BL. The vertical parts CP_V of the channel pattern CP may cover the sides facing each other of the adjacent first insulating patterns 120 in the first direction DR1.

According to an embodiment of FIG. 6 and FIG. 7, unlike the embodiment of FIG. 1 to FIG. 3, the vertical parts CP_V of the channel pattern CP may each be connected to the different landing pads LP spaced apart in the first direction DR1. The adjacent landing pads LP, respectively connected to the vertical parts CP_V of the channel pattern CP, may be spaced apart in the first direction DR1 by the interlayer insulating layer 140. The landing pad LP may be in contact with the upper surface of any one of the vertical parts CP_V of the channel pattern CP. The landing pad LP may have a width smaller than the width of the channel pattern CP along the first direction DR1.

According to the embodiment of FIG. 6 and FIG. 7, two word lines WL may be positioned between the vertical parts CP_V of the channel pattern CP. The two word lines WL positioned between the vertical parts CP_V of the channel pattern CP may include a first word line WL1 and a second word line WL2 spaced apart in the first direction. The third insulating pattern 160 may be positioned between the first word line WL1 and the second word line WL2.

The first word line WL1 and the second word line WL2 may each include an upper surface and a bottom surface facing in the third direction DR3, and both sides facing in the first direction DR1. The bottom surface and one side of each of the first word line WL1 and the second word line WL2 may be in contact with the gate insulating pattern Gox. The bottom surface of each of the first word line WL1 and the second word line WL2 may face the horizontal part CP_H of the channel pattern CP with the gate insulating pattern Gox in between. One side of each of the first word line WL1 and the second word line WL2 may face the vertical parts CP_V of the channel pattern CP with the gate insulating pattern Gox in between. The upper surface of each of the first word line WL1 and the second word line WL2 may be in contact with the second insulating pattern 130. The upper surface of the first word line WL1 and the second word line WL2 may be positioned at substantially the same vertical level as the upper surface of the vertical parts CP_V of the channel pattern CP. The other sides of the first word line WL1 and the second word line WL2 may face each other. The other side of each of the first word line WL1 and the second word line WL2 may be in contact with the third insulating pattern 160.

The third insulating pattern 160 may be in contact with the opposing sides of the first word line WL1 and the second word line WL2. The third insulating pattern 160 may be in contact with the upper surface of the gate insulating pattern Gox positioned between the bottom surfaces of the first word line WL1 and the second word line WL2. The third insulating pattern 160 may be in contact with the bottom surface of the second insulating pattern 130 positioned between the upper surfaces of the first word line WL1 and the second word line WL2. Although not shown, the third insulating pattern 160 may extend in the second direction DR2 along the first word line WL1 and the second word line WL2.

On a cross-section cut along second direction DR2 and third direction DR3, the first word line WL1 may cover the upper surfaces of the bit lines BL arranged and spaced apart in the second direction DR2. The part of the first word line WL that covers the upper surfaces of the bit lines BL may overlap with the upper surfaces of the bit lines BL in the third direction DR3. The first word line WL1 may include portions positioned between the bit lines BL arranged in the second direction DR2. The portions of the first word line WL1 positioned between the bit lines BL arranged in the second direction DR2 may overlap with the sides of the bit lines BL in the second direction DR2.

In FIG. 7, it is shown that the first word line WL1 extends in the second direction DR2, covers the upper surfaces of the bit lines BL, and includes the portions positioned between the bit lines BL arranged in the second direction DR2, but the above-described contents may be also applied equally or substantially similarly to the second word line WL2 and the third insulating pattern 160.

According to the embodiment of FIG. 6 and FIG. 7, like the embodiment of FIG. 1 to FIG. 3, as the contact area of the bit line BL and the channel pattern CP increases, the contact resistance may decrease. Additionally, the first word line WL1 and the second word line WL2 include the portions positioned between the adjacent bit lines BL, and thus they may serve as a shield wire between the adjacent bit lines BL. Accordingly, the electrical characteristics of the semiconductor device may be improved.

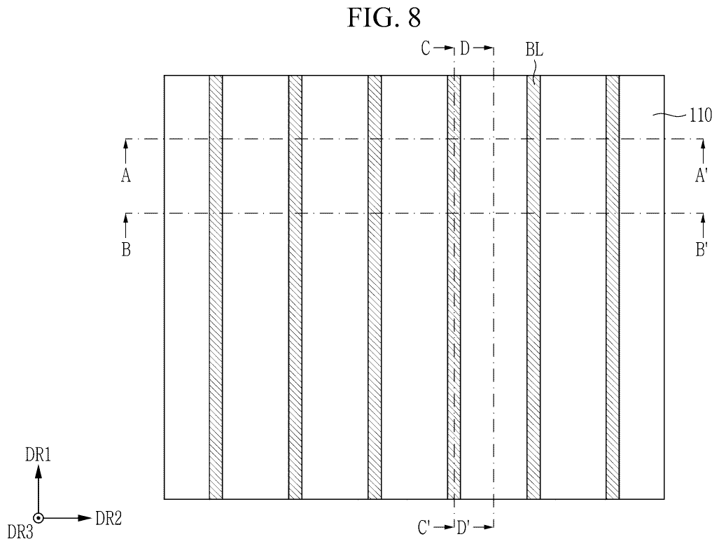

Hereinafter, the manufacturing method of the semiconductor device according to the embodiment of FIG. 1 to FIG. 3 is described with reference to FIG. 8 to FIG. 34. In FIG. 8 to FIG. 34, for convenience, although the substrate 100 and the core and peripheral circuits SA of FIG. 1 to FIG. 3 are omitted, the lower insulation layer 110 may be positioned on the substrate 100 and the core and peripheral circuits SA.

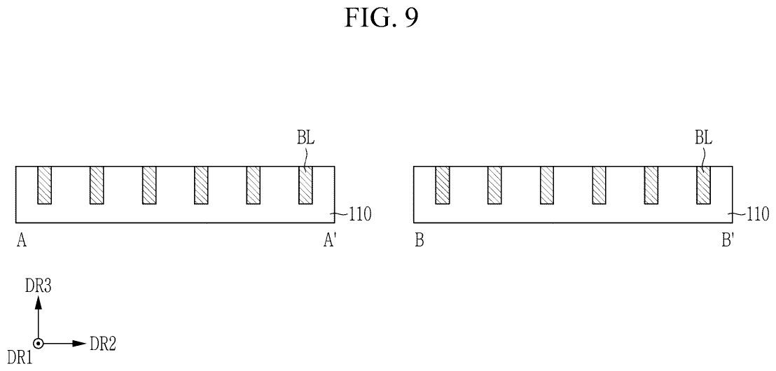

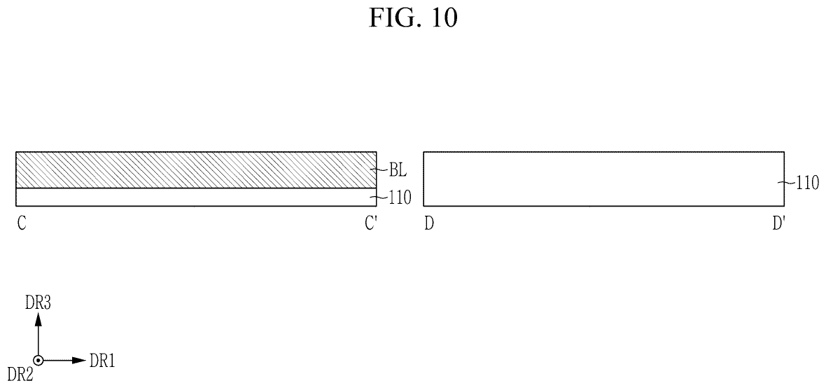

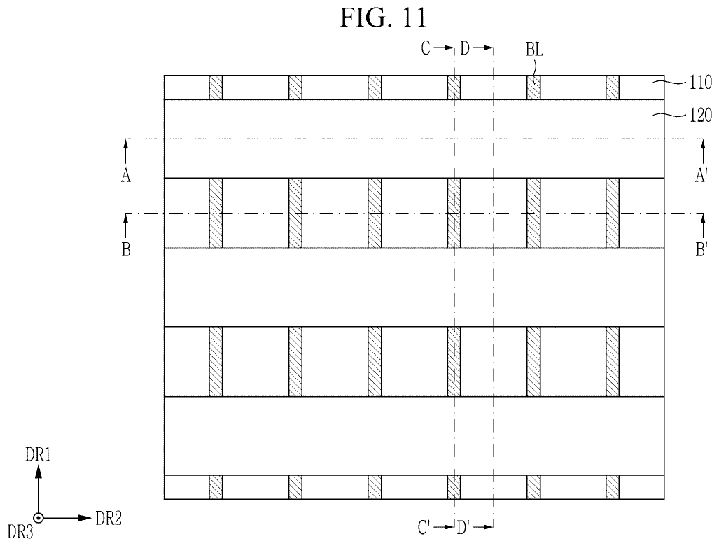

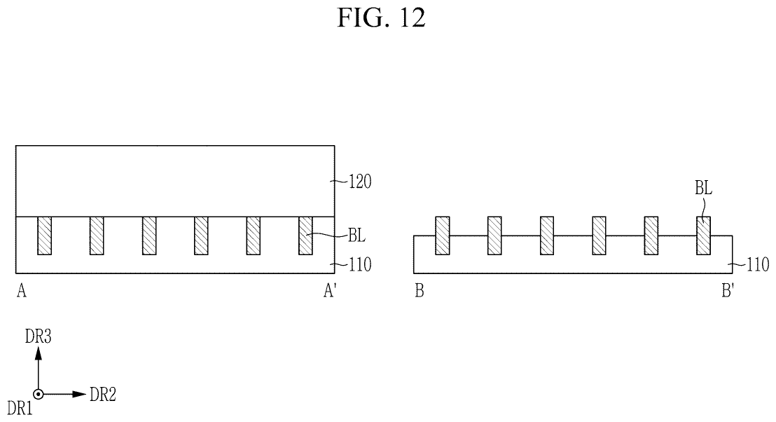

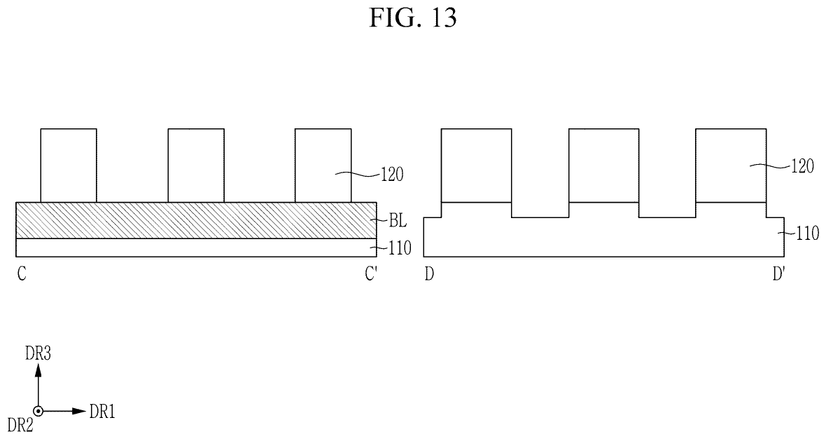

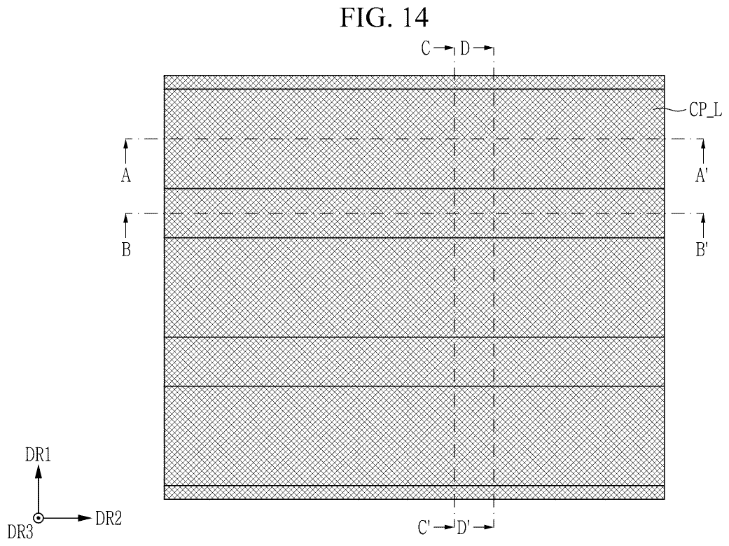

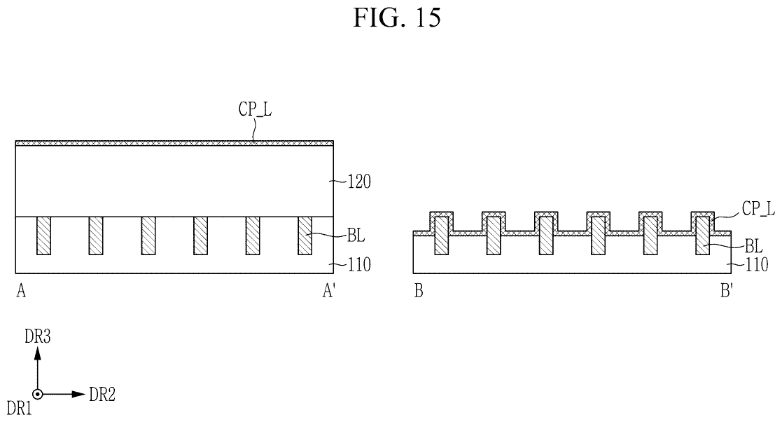

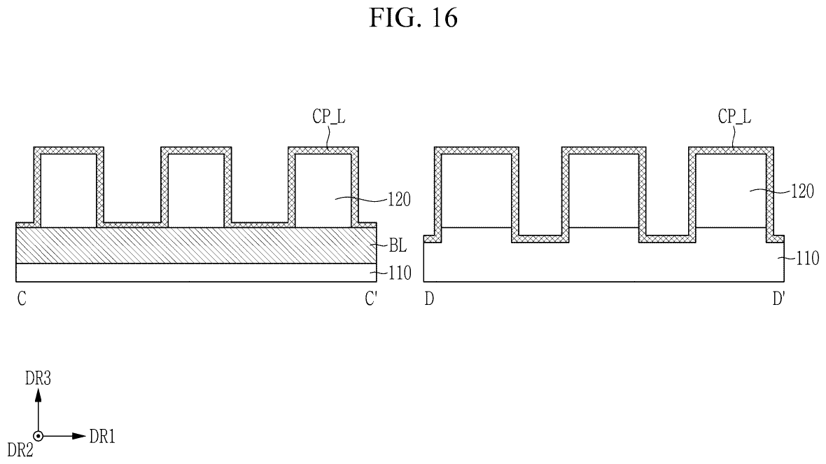

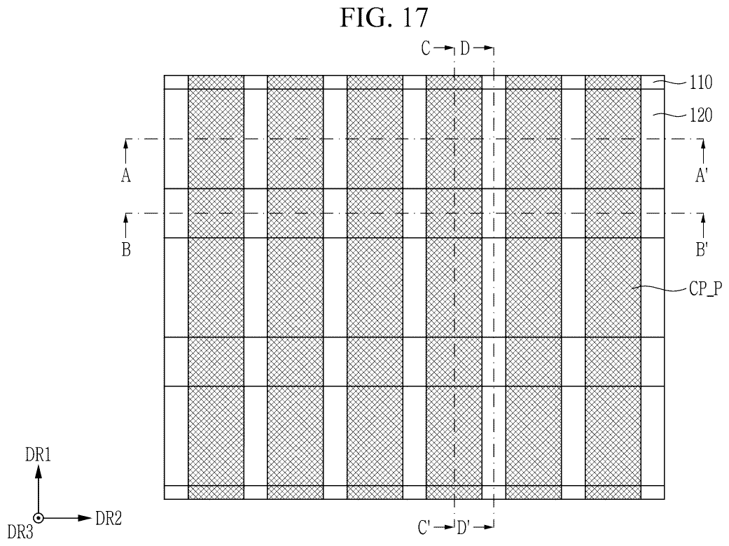

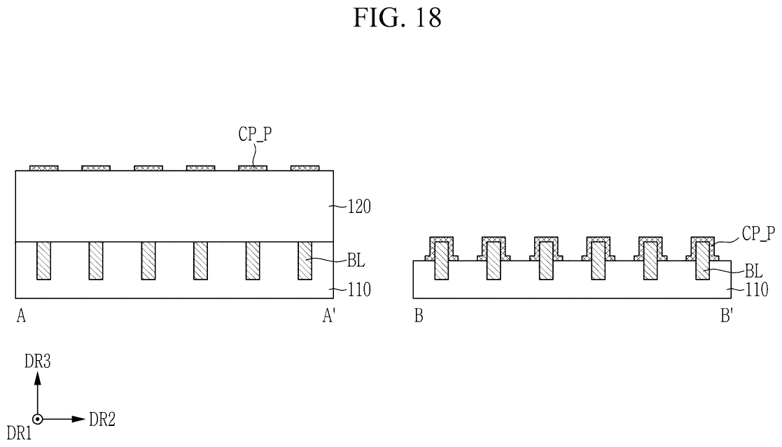

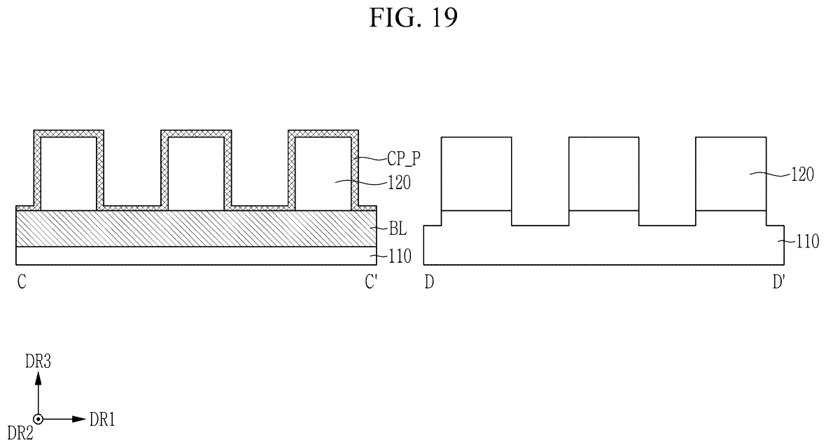

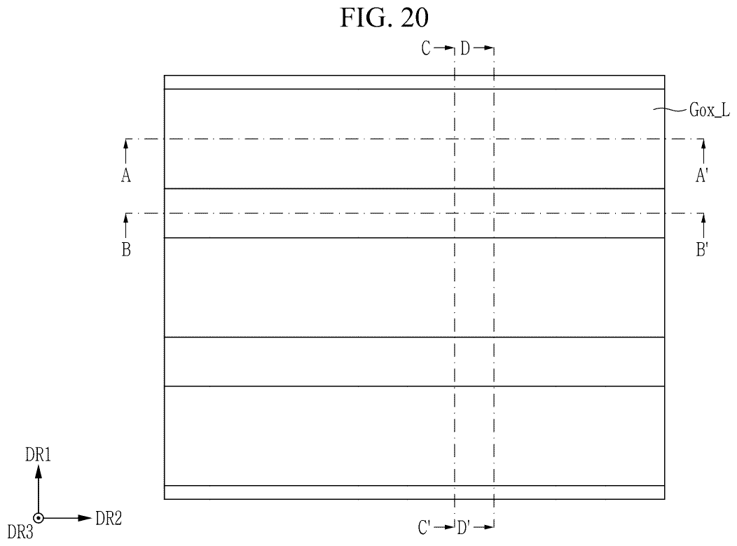

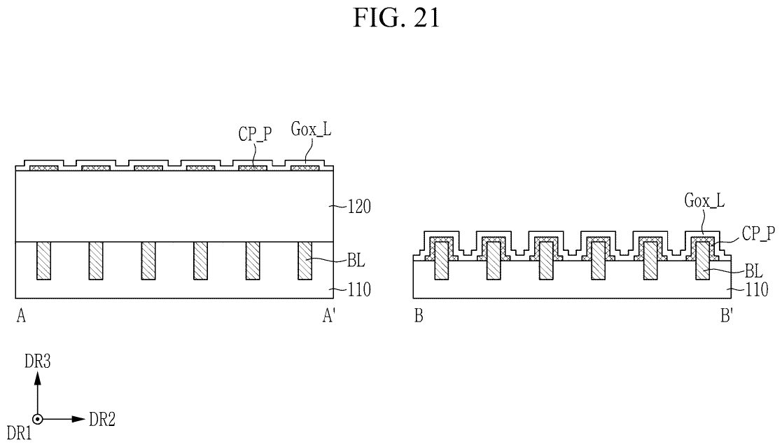

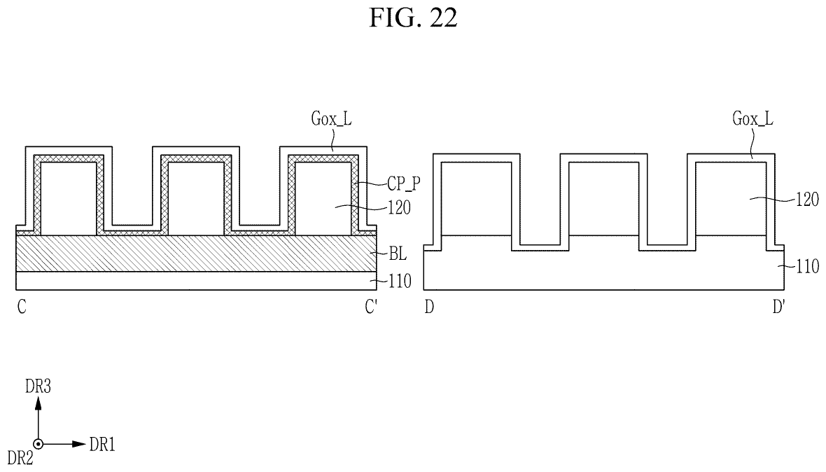

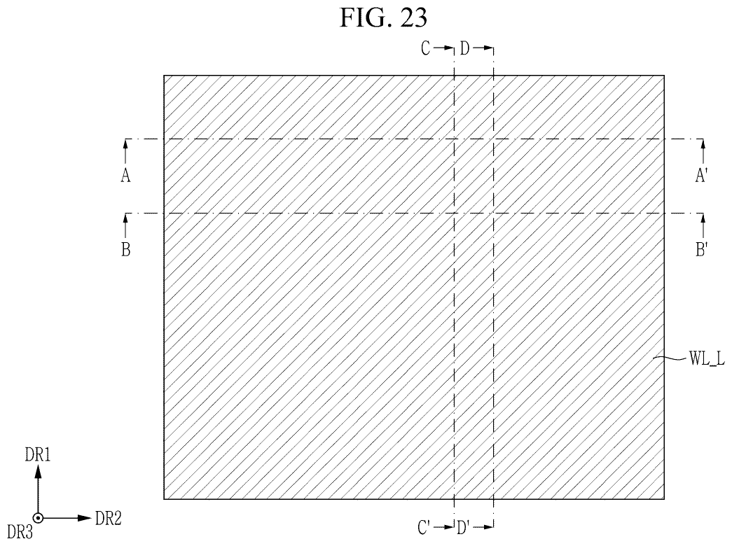

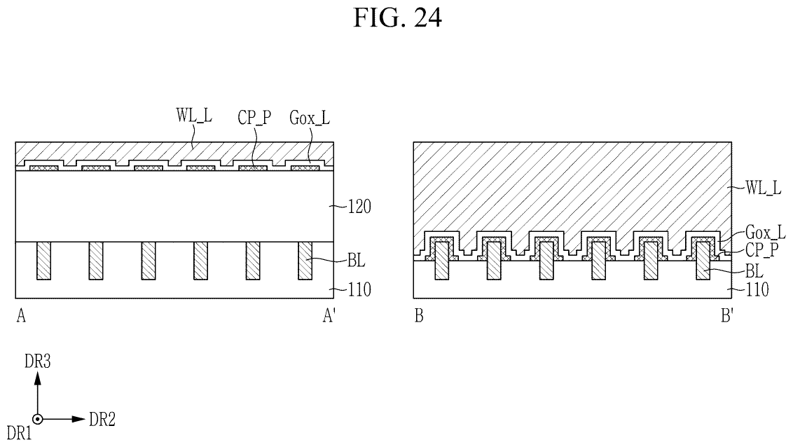

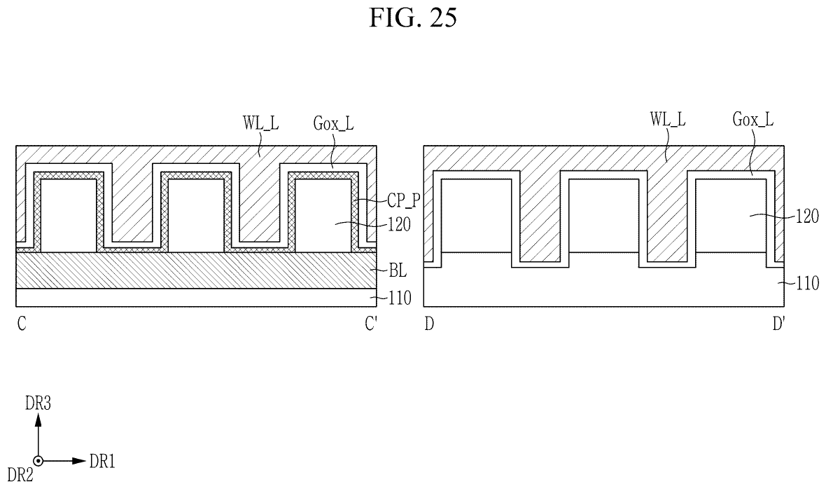

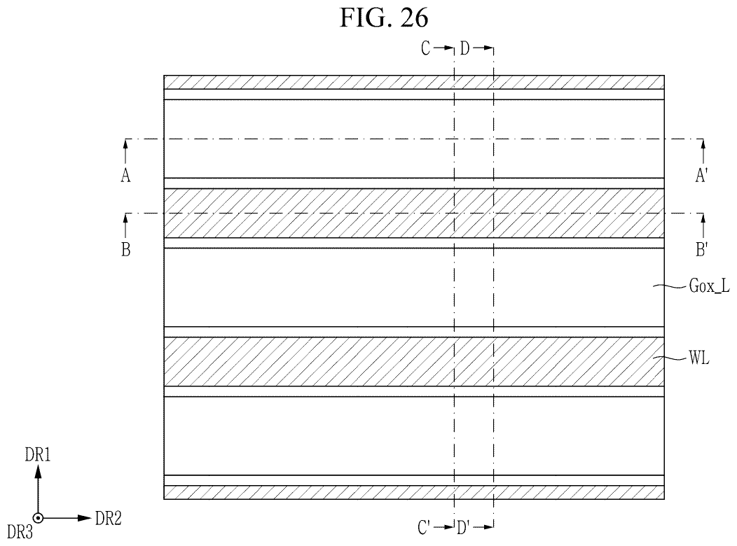

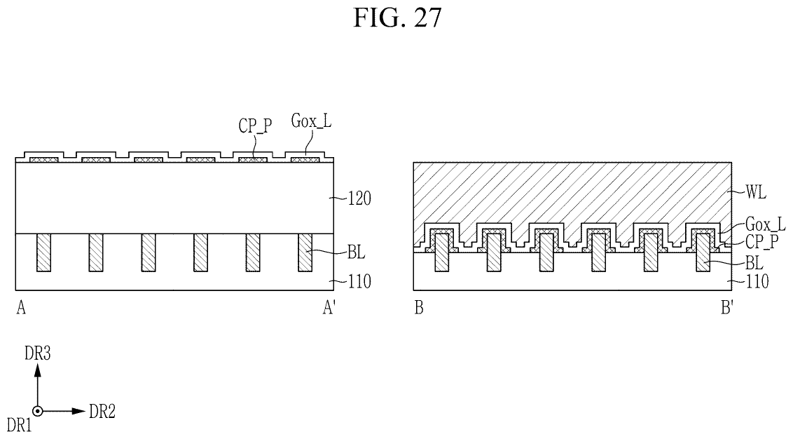

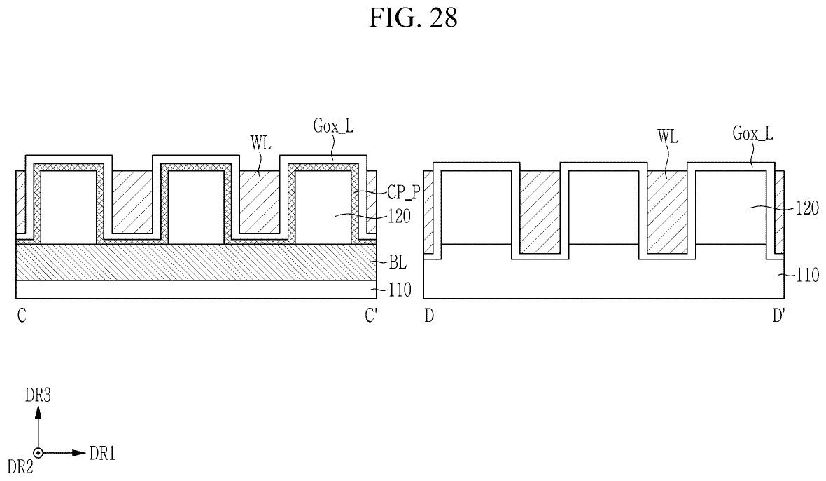

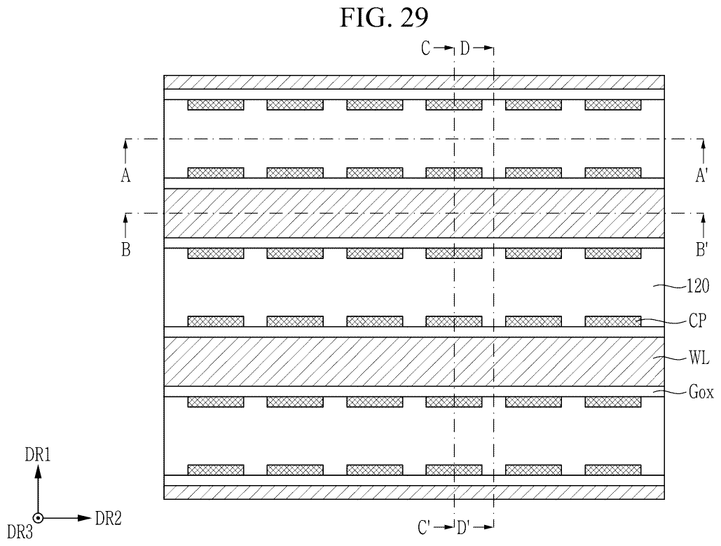

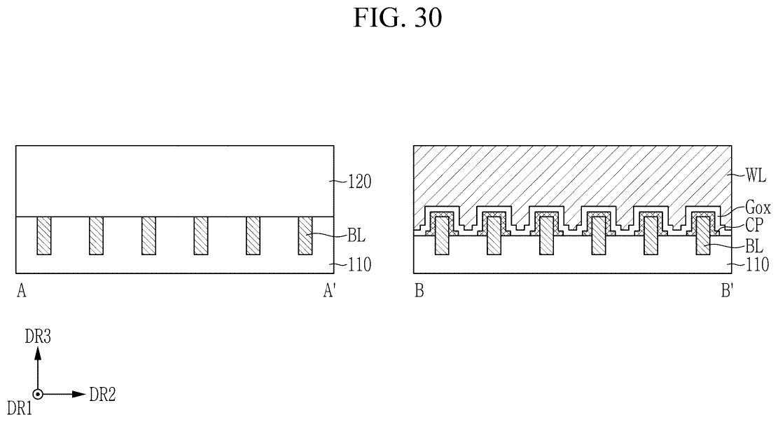

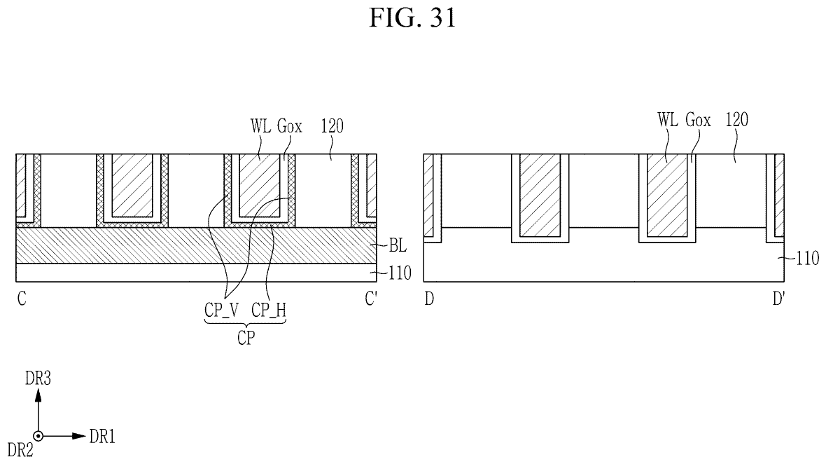

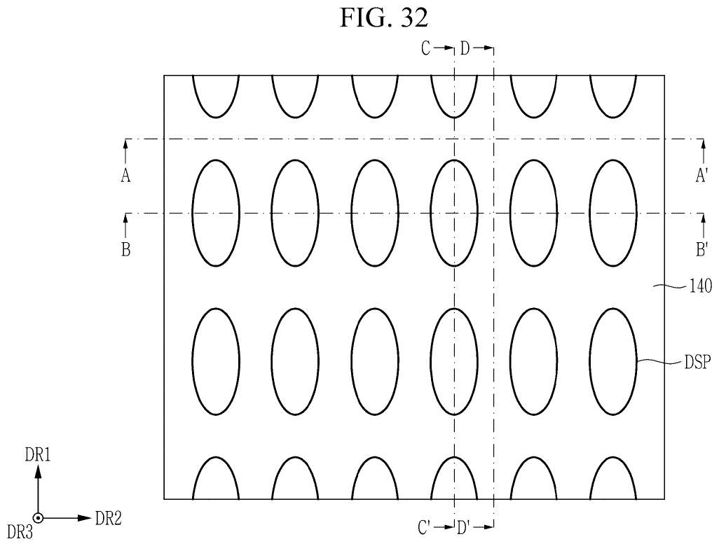

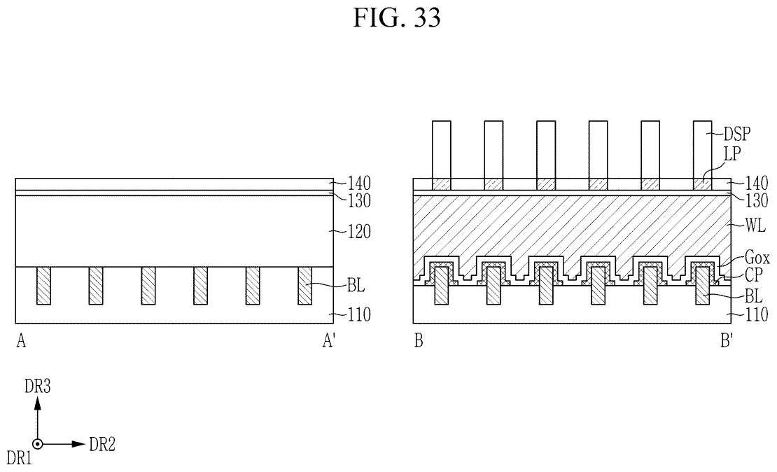

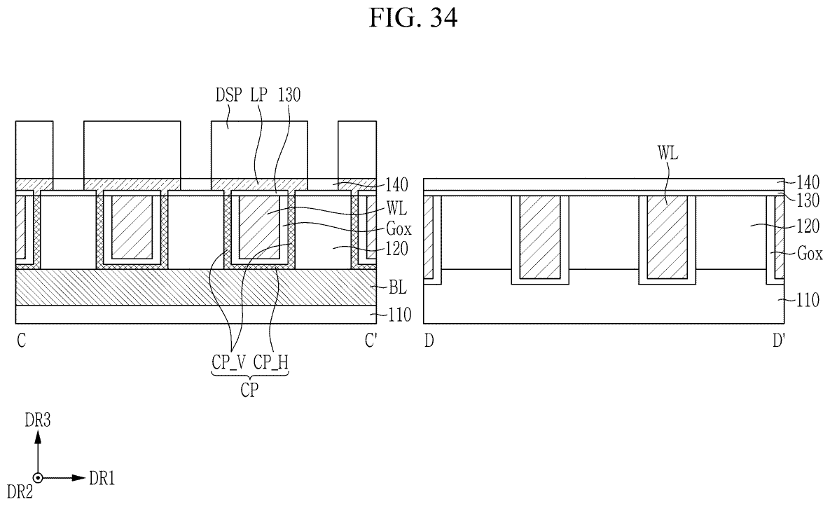

FIG. 8, FIG. 11, FIG. 14, FIG. 17, FIG. 20, FIG. 23, FIG. 26, FIG. 29, and FIG. 32 are layout views showing a manufacturing method of a semiconductor device according to an example embodiment. FIG. 9, FIG. 10, FIG. 12, FIG. 13, FIG. 15, FIG. 16, FIG. 18, FIG. 19, FIG. 21, FIG. 22, FIG. 24, FIG. 25, FIG. 27, FIG. 28, FIG. 30, FIG. 31, FIG. 33, and FIG. 34 are cross-sectional views showing a manufacturing method of a semiconductor device according to an example embodiment. FIG. 9, FIG. 12, FIG. 15, FIG. 18, FIG. 21, FIG. 24, FIG. 27, FIG. 30, and FIG. 33 are the views respectively showing the cross-sections take along the lines A-A′ and B-B′ of FIG. 8, FIG. 11, FIG. 14, FIG. 17, FIG. 20, FIG. 23, FIG. 26, FIG. 29, and FIG. 32. FIG. 10, FIG. 13, FIG. 16, FIG. 19, FIG. 22, FIG. 25, FIG. 28, FIG. 31, and FIG. 34 are the views respectively showing the cross-sections take along the lines C-C′ and D-D′ of FIG. 8, FIG. 11, FIG. 14, FIG. 17, FIG. 20, FIG. 23, FIG. 26, FIG. 29, and FIG. 32.

Referring to FIG. 8 to FIG. 10, a plurality of bit lines BL surrounded by a lower insulation layer 110 may be formed.

For example, bit lines BL may be formed by depositing a bit line material layer on an insulating material layer and patterning the bit line material layer. The plurality of bit lines BL may be arranged to be spaced apart along the second direction DR2. Each of the bit lines BL may have a bar or line shape that extends lengthwise in the first direction DR1.

Next, a lower insulation layer 110 may be formed by further depositing an insulating material identical to the insulating material layer to fill the space between the bit lines BL and to cover the upper surface of the bit lines BL. The insulating material may be, for example, silicon nitride, but embodiments are not limited thereto.

Next, the upper surface of the lower insulation layer 110 may be planarized to be the same vertical level as the upper surfaces of the bit lines BL. The upper surface of the lower insulation layer 110 and the upper surfaces of the bit lines BL may be positioned at substantially the same vertical level.

Referring to FIG. 11 to FIG. 13, a plurality of first insulating patterns 120 extending in the second direction DR2 may be formed on the upper surface of the lower insulation layer 110 and the bit lines BL. For example, the second direction DR2 may be vertical to the first direction DR1.

For example, the first insulating material layer may be deposited on the upper surfaces of the lower insulation layer 110 and the bit lines BL, and the first insulating material layer may be patterned to form first insulating patterns 120. The plurality of first insulating patterns 120 may be arranged to be spaced apart along the first direction DR1. The first insulating pattern 120 may be extended in the second direction DR2 across the bit line BL.

The first insulating material layer may include a material with an etch selectivity against the lower insulation layer 110. The first insulating material layer may be formed of or include, for example, silicon oxide, but embodiments are not limited thereto.

Next, the upper surface of the lower insulation layer 110 may be etched back. For example, only the upper surface of the lower insulation layer 110 may be etched using an etching solution that has an etch selectivity against the material of the first insulating pattern 120 and the material of the lower insulation layer 110. The upper surface of the lower insulation layer 110 may be positioned at a lower vertical level than the upper surfaces of the bit lines BL. In an embodiment, the upper surface of the lower insulation layer 110 may be positioned between the upper surface and the bottom surfaces of the bit lines BL, but embodiments are not limited thereto.

As shown in the embodiment of FIG. 4, the upper surface of the lower insulation layer 110 may be positioned at substantially the same vertical level as the bottom surface of the bit line BL. By adjusting the etching degree of the lower insulation layer 110, the height of the upper surface of the lower insulation layer 110 may be adjusted.

Referring to FIG. 14 to FIG. 16, a channel material layer CP_L may be formed to conformally cover the first insulating patterns 120, the bit lines BL, and the lower insulation layer 110. For example, the channel material layer CP_L may be deposited using an atomic layer deposition (ALD) process, but the present disclosure is not limited thereto, and the channel material layer CP_L may be formed using various methods.

The channel material layer CP_L may be formed of or include, for example, an oxide semiconductor material. According to an embodiment, the channel material layer CP_L may be formed of or include indium gallium zinc oxide (IGZO). However, embodiments are not limited to this, and the material included in the channel material layer CP_L can be variously changed to other oxide semiconductor materials or other materials.

On a cross-section cut along second direction DR2 and third direction DR3, the channel material layer CP_L may cover the upper surface and both sides of the first insulating pattern 120. The channel material layer CP_L may cover the upper part of both sides of the bit lines BL, which is positioned at a higher vertical level than the upper surface of the bit line BL and the upper surface of the lower insulation layer 110. The channel material layer CP_L may cover the upper surface of the lower insulation layer 110 positioned between the plurality of bit lines BL arranged in the second direction DR2.

On a cross-section cut along the first direction DR1 and the third direction DR3, the channel material layer CP_L may cover the upper surface and both sides of the first insulating pattern 120. The channel material layer CP_L may cover the upper surfaces of the bit lines BL exposed between the plurality of first insulating patterns 120 arranged in the first direction DR1. The channel material layer CP_L may cover both sides of the parts protruded toward the third direction DR3 among the lower insulation layer 110. The first insulating pattern 120 may be positioned right above the protruded part of the lower insulation layer 110. The protruded parts of the lower insulation layer 110 may be parts that are not etched because they are covered with the first insulating pattern 120 in the etch back process of the lower insulation layer 110. The protruded parts of the lower insulation layer 110 may have an upper surface of substantially the same height as the upper surfaces of the bit lines BL. The channel material layer CP_L may cover the upper surface of the lower insulation layer 110 exposed between the plurality of first insulating patterns 120 arranged in the first direction DR1.

Referring to FIG. 17 to FIG. 19, preliminary channel patterns CP_P may be formed by patterning the channel material layer CP_L. The preliminary channel patterns CP_P may be arranged to be spaced apart in the second direction DR2. On a plane, the preliminary channel pattern CP_P may be extended lengthwise in the first direction DR1. On a plane, the width of the preliminary channel pattern CP_P along the second direction DR2 may be larger than the width of the bit lines BL along the second direction DR2.

The preliminary channel pattern CP_P may surround the upper part of the bit lines BL. The preliminary channel pattern CP_P may surround the portion of the bit lines BL positioned at a higher vertical level than the upper surface of the lower insulation layer 110. The preliminary channel pattern CP_P may cover the part positioned at a higher vertical level than the upper surface of the bit lines BL and the upper surface of the lower insulation layer 110 among both sides of the bit lines BL.

The preliminary channel patterns CP_P may be disposed to be spaced apart in the second direction DR2 on the upper surface of the first insulating pattern 120 extending along the second direction DR2. On a cross-section cut along the first direction DR1 and third direction DR3, the preliminary channel pattern CP_P may cover the upper surface of the first insulating patterns 120 arranged along the first direction DR1 and the upper surface of both sides of the bit lines BL.

Referring to FIG. 20 to FIG. 22, a gate insulating material layer Gox_L may be formed to conformally cover the first insulating patterns 120, the preliminary channel patterns CP_P, and the lower insulation layer 110. For example, the gate insulating material layer Gox_L may be deposited using an atomic layer deposition (ALD) process, but the method is not limited thereto, and the gate insulating material layer Gox_L may be formed using various methods.

The gate insulating material layer Gox_L may include silicon oxide, silicon oxynitride, a high dielectric constant material with a higher dielectric constant than silicon oxide, or a combination thereof. The high dielectric constant material may include metal oxide or metal oxynitride. The high dielectric constant material, for example, HfO₂, HfSiO, HfSiON, HfTaO, HfTiO, HfZrO, ZrO₂, Al₂O₃, or a combination thereof. However, embodiments are not limited to this, and the material included in the gate insulating material layer Gox_L may be changed in various ways.

On a cross-section cut along the second direction DR2 and the third direction DR3, the gate insulating material layer Gox_L may cover the upper surface and side surfaces of the preliminary channel patterns CP_P arranged in second direction DR2. The gate insulating material layer Gox_L may cover the upper surface of the first insulating pattern 120 exposed between preliminary channel patterns CP_P arranged in the second direction DR2. The gate insulating material layer Gox_L may cover the upper surface of the lower insulation layer 110 exposed between the preliminary channel patterns CP_P arranged in the second direction DR2.

On a cross-section cut along the first direction DR1 and the third direction DR3, the gate insulating material layer Gox_L may cover the surface of the preliminary channel pattern CP_P running along the first direction DR1. The gate insulating material layer Gox_L may cover the upper surface and side of the first insulating patterns 120 and the upper surface and side of the lower insulation layer 110, which are exposed without being covered with the preliminary channel pattern CP_P.

Referring to FIG. 23 to FIG. 25, a word line material layer WL_L may be formed on the gate insulating material layer Gox_L. The word line material layer WL_L, for example, can be deposited using a chemical vapor deposition (CVD), a physical vapor deposition (PVD), or an ALD process, but embodiments are not limited thereto.

The word line material layer WL_L may include, for example, a doped polysilicon, a metal, a conductive metal nitride, a conductive metal silicide, a conductive metal oxide, or combinations thereof. The word line material layer WL_L, for example, may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but embodiments are not limited thereto.

On a cross-section cut along the second direction DR2 and the third direction DR3, the word line material layer WL_L may fill in the space remaining after the preliminary channel pattern CP_P and the gate insulating material layer Gox_L are formed between the bit lines BL adjacent in the second direction DR2. The word line material layer WL_L may be formed thicker than the thickness of the first insulating pattern 120 along the third direction DR3. The word line material layer WL_L may be positioned on the upper surface of the first insulating pattern 120.

On a cross-section cut along the first direction DR1 and the third direction DR3, the word line material layer WL_L may be filled in the space remaining after the preliminary channel pattern CP_P and the gate insulating material layer Gox_L are formed between the first insulating patterns 120 arranged in the first direction DR1. The word line material layer WL_L may be formed to cover the upper surfaces of the first insulating patterns 120 arranged in the first direction DR1. The word line material layer WL_L may be filled in the space remaining after the gate insulating material layer Gox_L is formed between the protruded parts of the lower insulation layer 110 arranged in the first direction DR1. The bottom surfaces of the word line material layer WL_L, which is positioned between the protruded parts of the lower insulation layer 110, may be positioned at a lower vertical level than the upper surfaces of the bit lines BL.

Referring to FIG. 26 to FIG. 28, the word line material layer WL_L may be etched back to form a plurality of word lines WL.

For example, the word line material layer WL_L may be etched back to have an upper surface at substantially the same vertical level as the upper surface of the first insulating pattern 120. Accordingly, the word line material layer WL_L may be disconnected in the first direction DR1.

The plurality of word lines WL may be disposed to be spaced apart in the first direction DR1.

On a cross-section cut along the second direction DR2 and the third direction DR3, the word lines WL may extend lengthwise in the second direction DR2. The word lines WL may cover the upper surface of the bit lines BL arranged along the second direction DR2. The word lines WL may include the portions positioned between the bit lines BL adjacent to the second direction DR2. Each of the portions of the word lines WL positioned between the adjacent bit lines BL may cover the opposing sides of the adjacent bit lines BL. The word lines WL may overlap with the bit lines BL in the third direction DR3 and the second direction DR2.

On a cross-section cut along the first direction DR1 and the third direction DR3, the word lines WL may be positioned between the first insulating patterns 120 arranged in the first direction DR1. The word lines WL may be filled in the space remaining after the preliminary channel pattern CP_P and the gate insulating material layer Gox_L are formed between the first insulating patterns 120 arranged in the first direction DR1. The word lines WL may be filled in the space left after the gate insulating material layer Gox_L is formed between the protruded parts of the lower insulation layer 110 arranged in the first direction DR1. The bottom surfaces of the word lines WL, which are positioned between the protruded parts of the lower insulation layer 110, may be positioned at a lower vertical level than the upper surfaces of the bit lines BL. The word lines WL may fill in the space left after the gate insulating material layer Gox_L is formed between the first insulating patterns 120 positioned above the protruded parts of the lower insulation layer 110.

According to an embodiment, the upper surface of the word lines WL may be positioned at substantially the same vertical level as the upper surface of the first insulating pattern 120, but embodiments are not limited thereto.

As shown in the embodiment of FIG. 5, the upper surface of the word line WL may be positioned at a lower vertical level than the upper surface of the first insulating pattern 120. By adjusting the etching degree of the word lines WL, the height of the upper surfaces of word lines WL may be adjusted. In the embodiment where the upper surfaces of the word re WL has positioned at a lower vertical level than the upper surface of the first insulating pattern 120, an additional insulating pattern (e.g., additional insulating pattern 150 in FIG. 5) may be formed on the word lines WL. At this time, the insulating pattern may have an upper surface of substantially the same vertical level as the upper surface of the first insulating pattern 120.

According to an embodiment, the word lines WL may completely fill in the space remaining after the preliminary channel pattern CP_P and the gate insulating material layer Gox_L) are formed between the first insulating patterns 120 arranged in the first direction DR1, but embodiments are not limited thereto.

As shown in the embodiment of FIG. 6 and FIG. 7, the word lines WL may be separated in the first direction DR1 between the first insulating patterns 120 arranged in the first direction DR1. A first word line WL1 and a second word line WL2 spaced apart in the first direction DR1 may be formed between the first insulating patterns 120 arranged in the first direction DR1. For example, as the word line material layer WL_L is formed conformally in the process of FIG. 23 to FIG. 25 and patterned to be separated between the first insulating patterns 120 arranged in the first direction DR1 in the process of FIG. 26 to FIG. 28, the first word line WL1 and the second word line WL2 of the embodiment shown in FIG. 6 and FIG. 7 may be formed.

Referring to FIG. 29 to FIG. 31, a plurality of gate insulating patterns Gox and a plurality of channel patterns CP may be formed by etching back the gate insulating material layer Gox_L and the preliminary channel patterns CP_P.

For example, the gate insulating material layer Gox_L may be etched back to have an upper surface at substantially the same vertical level as the upper surface of the first insulating pattern 120. Accordingly, the gate insulating material layer Gox_L may be separated in the first direction DR1. The plurality of gate insulating patterns Gox may be disposed to be spaced apart in the first direction DR1.

For example, the preliminary channel patterns CP_P may be etched back to have an upper surface at substantially the same vertical level as the upper surface of the first insulating pattern 120. Accordingly, the preliminary channel patterns CP_P may be separated into not only the second direction DR2 but also the first direction DR1. The plurality of channel patterns CP may be spaced apart in the first direction DR1 and the second direction DR2. For example, the plurality of channel patterns CP may be arranged in a matrix form.

On a cross-section cut along the second direction DR2 and the third direction DR3, the portion of the preliminary channel patterns CP_P and the portion of the gate insulating material layer Gox_L positioned on the upper surface of the first insulating pattern 120 extending in the second direction DR2 may be removed. The channel pattern CP may surround three surfaces of the bit line BL. The channel pattern CP may surround the upper surface and both sides of the bit line BL. The channel pattern CP may surround the upper part of both sides extending from the upper surface of bit line BL to the third direction DR3. The upper part of both sides of the bit line BL may refer to parts positioned at a higher vertical level than the upper surface of the lower insulation layer 110. The channel pattern CP may surround parts of both sides of the bit line BL that are positioned at a higher vertical level than the upper surface of the bit line BL and the upper surface of the lower insulation layer 110.

On a cross-section cut along the first direction DR1 and the third direction DR3, the portion of the preliminary channel pattern CP_P and the portion of the gate insulating material layer Gox_L positioned on the upper surfaces of the first insulating patterns 120 arranged in the first direction DR1 may be removed. The uppermost surfaces of the channel patterns CP and gate insulating patterns Gox may be positioned at substantially the same vertical level as the upper surface of the first insulating pattern 120. The channel patterns CP and the gate insulating patterns Gox may be positioned between the first insulating patterns 120 adjacent in the first direction DR1.

The channel pattern CP may include a horizontal part CP_H covering the upper surface of the bit line BL and vertical parts CP_V extending in the third direction DR3 from the horizontal part CP_H and covering the facing sides of the first insulating patterns 120 adjacent in the first direction DR1. The vertical parts CP_V may be arranged to face each other between the first insulating patterns 120 adjacent to each other in the first direction DR1.

The word line WL may be positioned above the channel pattern CP. The word line WL may be positioned above the horizontal part CP_H of the channel pattern CP. The word line WL may be positioned between the vertical parts CP_V of the channel pattern CP.

The gate insulating pattern Gox may be positioned between the channel pattern CP and the word line WL.

Referring to FIG. 32 to FIG. 34, a second insulating pattern 130, a plurality of landing pads LP, an interlayer insulating layer 140, and data storing patterns DSP may be formed.

First, a second insulating material layer may be deposited on the word lines WL, the gate insulating patterns Gox, and the channel patterns CP, and the second insulating material layer may be patterned to form a second insulating pattern 130 exposing the upper surface of the vertical parts CP_V of the channel patterns CP. The second insulating material layer may be formed of or include, for example, silicon nitride, but embodiments are not limited thereto.

Next, a landing pad material layer may be deposited. The landing pad material layer may include a doped polysilicon, a metal, a conductive metal nitride, a conductive metal oxide, or combinations thereof. For example, the landing pad material layer may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx or a combination thereof, but embodiments are not limited thereto. The landing pad material layer may fill recesses including the sidewall defined by the second insulating pattern 130 and the bottom defined by the channel pattern CP. Accordingly, the landing pad material layer may be in contact with the upper surface of the vertical parts CP_V of the channel patterns CP. The landing pad material layer may be formed to cover the upper surface of the second insulating pattern 130.

Next, after patterning the landing pad material layer to form holes that expose the upper surface of the second insulating pattern 130, an interlayer insulating layer 140 may be buried in the holes, and then a planarization process may be performed. Accordingly, landing pads LP may be formed. The landing pads LP may be landing pads LP spaced apart in the first direction DR1 and the second direction DR2. The landing pad LP may be connected to the vertical parts CP_V of the channel pattern CP. The landing pad LP may be in contact with the upper surfaces of the vertical parts CP_V of the channel pattern CP.

According to an embodiment, the vertical parts CP_V of the channel pattern CP may be connected to the same landing pad LP, but embodiments are not limited thereto. As in the embodiment shown in FIG. 6 and FIG. 7, the vertical parts CP_V of the channel pattern CP may each be connected to the different landing pads LP. In this case, in the patterning process of the landing pad material layer, the landing pad material layer may be disconnected in the first direction DR1 between the vertical parts CP_V of the channel pattern CP. The landing pads LP connected to each of the vertical parts CP_V of the channel pattern CP may be spaced apart in the first direction DR1, and the interlayer insulating layer 140 may be positioned between the landing pads LP.

Subsequently, data storing patterns DSP may be formed on the upper surface of the landing pads LP, respectively. In an embodiment, the data storing pattern DSP may be a capacitor including a lower electrode, a capacitor dielectric layer, and an upper electrode, in this case, the lower electrode may be in contact with the landing pad LP.

While this disclosure has been described in connection with what is presently considered to be an exemplary embodiment, it is to be understood that the disclosure is not limited to the disclosed embodiment, but, on the contrary, is intended to cover various modifications and equivalent arrangements included within the spirit and scope of the appended claims.

What is claimed is:

1. A semiconductor device comprising:
a substrate;
a lower insulation layer positioned above the substrate;
a bit line positioned above the lower insulation layer and extending parallel to the substrate in a first direction;
a first insulating pattern positioned above the bit line and extending in a second direction intersecting the first direction;
a channel pattern electrically connected to the bit line and covering a side of the first insulating pattern;
a word line extending in the second direction and spaced apart from the channel pattern;
a gate insulating pattern positioned between the channel pattern and the word line;
a second insulating pattern positioned above the word line, the gate insulating pattern, and the first insulating pattern; and
a landing pad electrically connected to the channel pattern,
wherein a part of the word line is positioned between a plurality of bit lines arranged spaced apart in the second direction.

2. The semiconductor device of claim 1, wherein:
the word line includes a first part covering upper surfaces of bit lines arranged in the second direction and extending in the second direction, and second parts extending in a third direction vertical to the substrate toward an upper surface of the lower insulation layer from a bottom surface of the first part, and
the second parts are each positioned between the bit lines adjacent in the second direction.

3. The semiconductor device of claim 2, wherein the first part of the word line overlaps the bit lines in the third direction, and the second parts of the word line respectively overlap the bit lines in the second direction.

4. The semiconductor device of claim 1, wherein the channel pattern is in contact with an upper surface and both sides of the bit line.

5. The semiconductor device of claim 4, wherein:
an upper surface of the lower insulation layer is positioned at a vertical level between the upper surface and a bottom surface of the bit line,
the channel pattern surrounds the upper surface of the bit line and a portion of the both sides of the bit line extending from the upper surface of the bit line, and
a part of the both sides of the bit line includes a part positioned at a higher vertical level than the upper surface of the lower insulation layer.

6. The semiconductor device of claim 4, wherein:
the upper surface of the lower insulation layer is positioned at the same vertical level as a bottom surface of the bit line, and
the channel pattern completely surrounds the upper surface of the bit line and the both sides of the bit line.

7. The semiconductor device of claim 1, further comprising:
an additional insulating pattern positioned between the word line and the second insulating pattern,
wherein the word line is separated from the second insulating pattern by the additional insulating pattern.

8. The semiconductor device of claim 1, wherein:
the first insulating pattern is a plurality of first insulating patterns,
the plurality of first insulating patterns are arranged and spaced apart along the first direction,
the channel pattern is positioned between first insulating patterns adjacent in the first direction of the plurality of first insulating patterns and includes a horizontal part covering the bit line and vertical parts extending from the horizontal part in a third direction perpendicular to the substrate and facing the first direction, and
the vertical parts are connected to the same landing pad.

9. The semiconductor device of claim 1, wherein:
the first insulating pattern is a plurality of first insulating patterns,
the plurality of first insulating patterns are arranged and spaced apart along the first direction,
the channel pattern is positioned between first insulating patterns adjacent in the first direction of the plurality of first insulating patterns and includes a horizontal part covering the bit line and vertical parts extending from the horizontal part in a third direction perpendicular to the substrate and facing the first direction, and
the vertical parts are each connected to different landing pads spaced apart in the first direction.

10. The semiconductor device of claim 9, wherein the word line includes a first word line and a second word line positioned above the horizontal part, positioned between the vertical parts, and spaced apart in the first direction.

11. The semiconductor device of claim 1, wherein the channel pattern includes indium gallium zinc oxide (IGZO).

12. A semiconductor device comprising:
a substrate;
a lower insulation layer positioned on the substrate;
a bit line positioned above the lower insulation layer and extending parallel to the substrate in a first direction;
a first insulating pattern positioned above the bit line and extending in a second direction intersecting the first direction;
a channel pattern electrically connected to the bit line and covering a side of the first insulating pattern;
a word line extending in the second direction and spaced apart from the channel pattern;
a gate insulating pattern positioned between the channel pattern and the word line;
a second insulating pattern positioned on the word line, the gate insulating pattern, and the first insulating pattern; and
a landing pad electrically connected to the channel pattern,
wherein the word line includes protruded parts protruding in a third direction vertical to the substrate towards an upper surface of the lower insulation layer, and
wherein each of the protruded parts of the word line is positioned between bit lines adjacent in the second direction.

13. The semiconductor device of claim 12, wherein each of the protruded parts of the word line overlap with the bit lines adjacent in the second direction.

14. The semiconductor device of claim 12, wherein three sides of the bit line are surrounded by the channel pattern.

15. The semiconductor device of claim 14, wherein:
a bottom surface of the bit line and a lower part of both sides of the bit line extending from the bottom surface of the bit line are surrounded by the lower insulation layer, and
an upper surface of the bit line and an upper part of both sides of the bit line extending from the upper surface are surrounded by the channel pattern.

16. The semiconductor device of claim 14, wherein:
an upper surface of the bit line and both sides of the bit line are surrounded by the channel pattern, and
a bottom surface of the bit line is in contact with the upper surface of the lower insulation layer.

17. The semiconductor device of claim 12, wherein:
the first insulating pattern and the channel pattern are alternately and repeatedly arranged along the first direction,
the channel pattern includes a horizontal part covering an upper surface of the bit line and vertical parts covering opposing sides of first insulating patterns adjacent in the first direction, and
one word line is positioned between the vertical parts.

18. The semiconductor device of claim 12, wherein:
the first insulating pattern and the channel pattern are alternately and repeatedly arranged along the first direction,
the channel pattern includes a horizontal part covering an upper surface of the bit line and vertical parts covering opposing sides of first insulating patterns adjacent in the first direction, and
two word lines spaced apart in the first direction are positioned between the vertical parts.

19. A semiconductor device comprising:
a substrate;
a lower insulation layer positioned on the substrate;
a bit line positioned above the lower insulation layer and extending parallel to the substrate in a first direction;
a first insulating pattern positioned above the bit line and extending in a second direction intersecting the first direction;
a channel pattern electrically connected to the bit line and covering a side of the first insulating pattern;
a word line extending in the second direction and spaced apart from the channel pattern;
a gate insulating pattern positioned between the channel pattern and the word line;
a second insulating pattern positioned on the word line, the gate insulating pattern, and the first insulating pattern; and
a landing pad electrically connected to the channel pattern,
wherein the bit line has an upper surface at a higher vertical level than the upper surface of the lower insulation layer, and
wherein a portion of the bit line positioned at a higher vertical level than the upper surface of the lower insulation layer overlaps with the word line in the second direction and in a third direction vertical to the substrate.

20. The semiconductor device of claim 19, wherein:
the channel pattern includes a first surface in contact with the upper surface of the bit line, and second surfaces in contact with both sides of the bit line, and
each of the second surfaces is in contact with the side of the bit line positioned at a higher vertical level than the upper surface of the lower insulation layer.
